(19) United States
(12) Patent Application Publication
(10) Pub. No.: US 2014/0301051 A1
(43) Pub. Date: Oct. 9, 2014

(54) FASTENING DEVICE FOR EXPANSION CARD

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventor: Li-Ren FU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/965,204

(22) Filed: Aug. 13, 2013

(30) Foreign Application Priority Data
Apr. 3, 2013 (CN) 201310114522X

(51) Int. Cl. H05K 7/12

(52) U.S. Cl. CPC H05K 7/12
USPC 361/759

(57) ABSTRACT

A fastening device for an expansion card includes a chassis and a fastener. The chassis includes a first rack, and a second rack behind the first rack. The second rack is fastened to a rear end of the expansion card. The fastener is pivotably and slidably connected to the first rack. A supporting portion is formed on the fastener. When the fastener is rotated to a first position, the fastener is in front of the first rack, when the fastener is rotated to a second position, the fastener is operable to be slid back to allow the supporting portion to support a front end of the expansion card.

### BACKGROUND

1. Technical Field

The present disclosure relates to a fastening device for fastening an expansion card in place.

2. Description of Related Art

Expansion cards are generally classified either as a full length type or as a half length type. In a server, a half of a full length type of an expansion card is generally fastened to a rack and connected to a riser card, and the other half of the full length type of expansion card is cantilevered. The cantilevered end of the expansion card tends to vibrate, which is harmful to data transmission of the expansion card.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device together with an expansion card, wherein the fastening device includes a fastener.

FIG. 2 is an enlarged view of a circled portion II of FIG. 1.

FIG. 3 is an enlarged view of the fastener of FIG. 1, viewed from another perspective.

FIG. 4 is an partial assembled, isometric view of FIG. 1.

FIGS. 5 and 6 are similar to FIG. 4, but showing different states.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

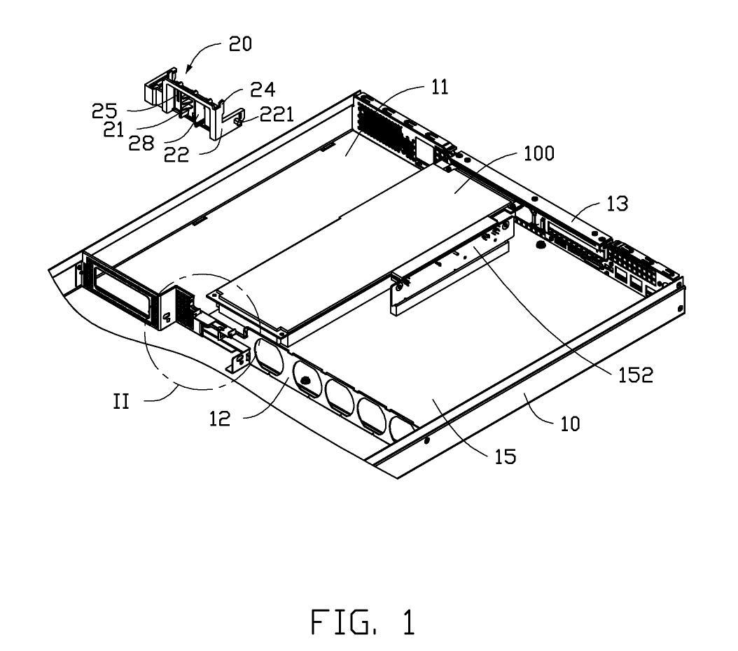

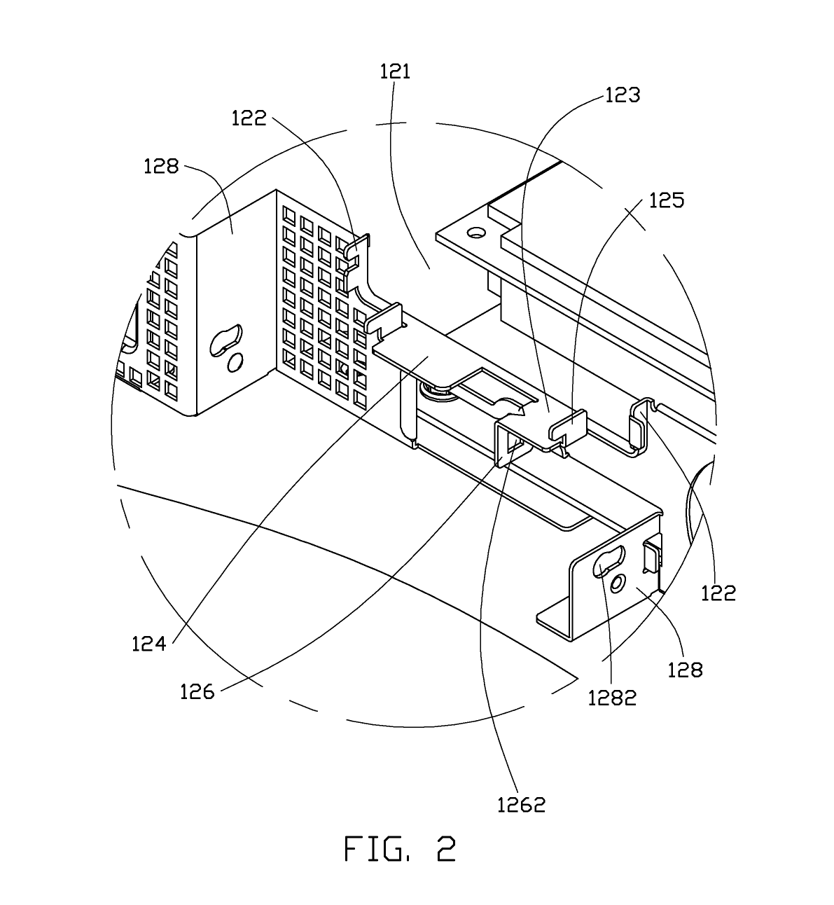

FIGS. 1 and 2 show an exemplary embodiment of a fastening device for an expansion card 100. The fastening device includes a chassis 10 and a fastener 20.

The chassis 10 includes a bottom plate 11, a first rack 12 extending up from a front end of the bottom plate 11, and a second rack 13 extending up from a rear end of the bottom plate 11. A circuit board 15 is mounted on the bottom plate 11. A riser card 152 is electrically connected to the circuit board 15, and is near the second rack 13. The expansion card 100 can be connected to the riser card 152 to communicate with the circuit board 15.

An opening 121 is defined in a top of the first rack 12. Two stop tabs 122 extend forward from opposite walls bounding the opening 121. A first supporting tab 123 and a second supporting tab 124 both extend forward from a bottom wall bounding the opening 121. A limitation tab 125 extends up from each of the first supporting tab 123 and second supporting tab 124. An engaging portion 126 extends down from an end of the first supporting tab 123 near the second supporting tab 124. The engaging portion 126 defines a hooking slot 1262. Two extension portions 128 extend forward from the first rack 12 and are located at opposite sides of the opening 121. Each extension portion 128 defines a through slot 1282.

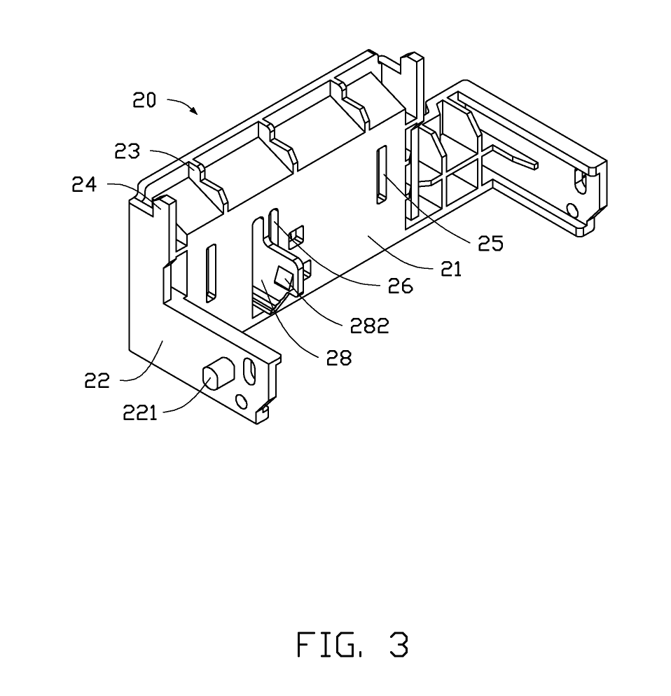

FIG. 3 shows the fastener 20 including a base plate 21, and two pivoting plates 22 extending back from lower portions of opposite ends of the base plate 21. A plurality of clamp tabs 23 is formed on a top of the base plate 21. Two supporting portions 24 are formed on opposite ends of the top of the base plate 21 and are located behind the clamp tabs 23. The base plate 21 defines two first through holes 25, and a second through hole 26 between the first through holes 25. A resilient portion 28 extends from the base plate 21, extending through the second through hole 26 and beyond front and rear sides of the base plate 21. A latch 282 extends from the resilient portion 28, and is located behind the second through hole 26. A pin 221 extends from an outer surface of each pivoting plate 22.

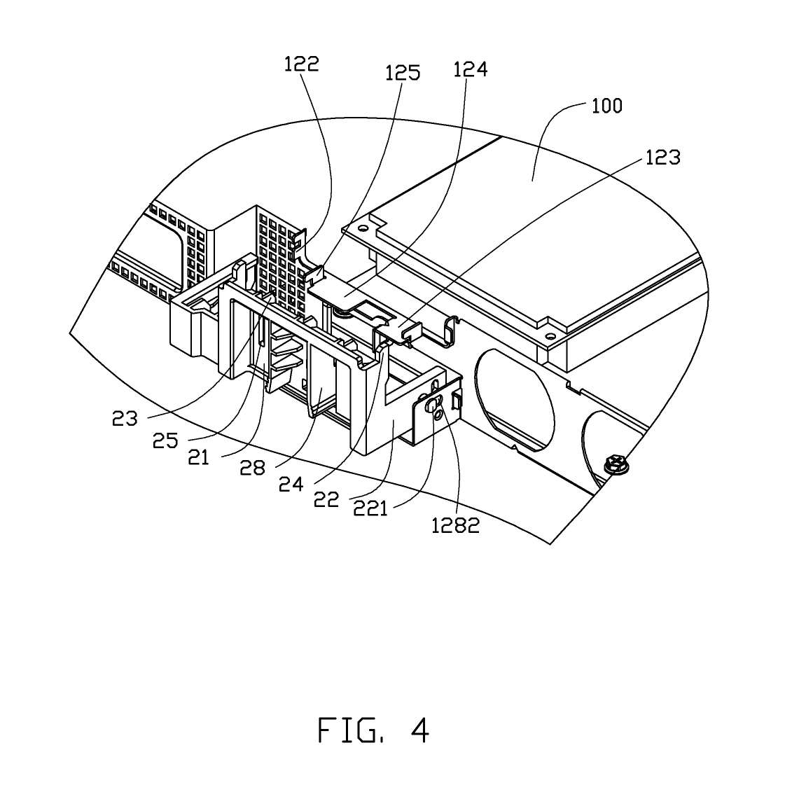

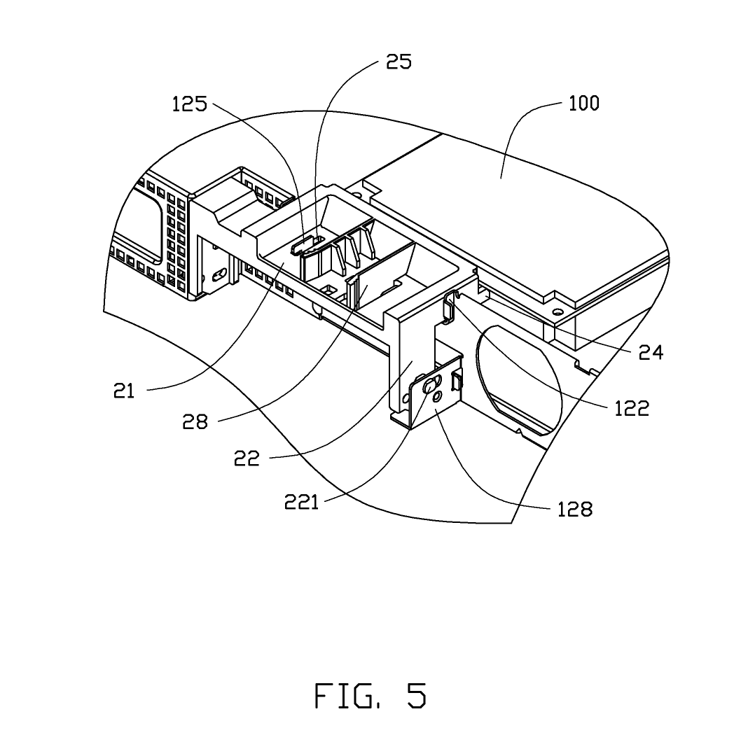

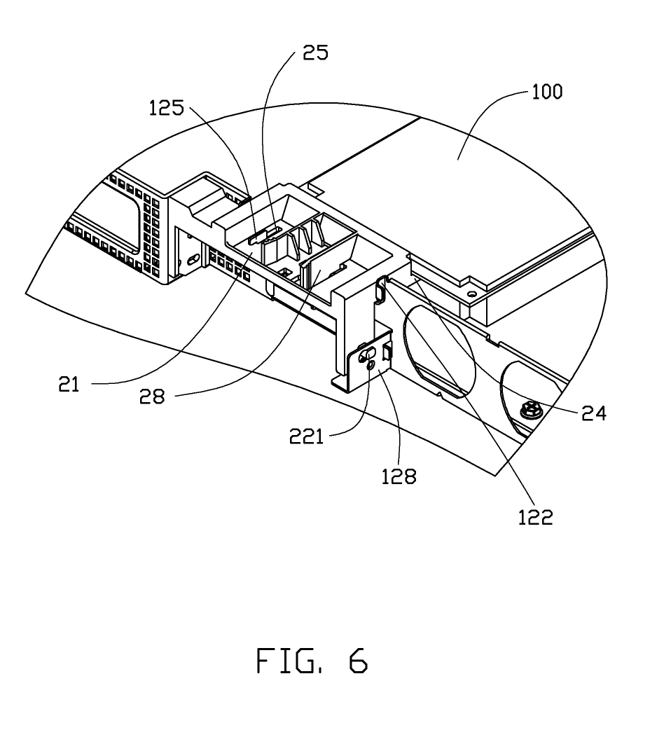

FIGS. 4-6 show in assembly, the fastener 20 is placed between the extension portions 128. The pins 221 extend through the through slots 1282, to slidably and pivotably connect the fastener 20 to the extension portions 128.

The fastener 20 is rotated to a first position. In the first position, the fastener 20 is in front of the first rack 12, to avoid obstructing the expansion card 100 to be mounted. The expansion card 100 is connected to the riser card 152, and a rear end of the expansion card 100 is fastened to the second rack 13. The fastener 20 is rotated back to a second position. In the second position, the limitation tabs 125 extend through the first through holes 25; the base plate 21 is supported on the first supporting tab 123 and second supporting tab 124; Opposite ends of the base plate 21 are blocked by the stop tabs 122; the clamp tabs 23 are above and in front of the expansion card 100; the supporting portions 24 are below and in front of the expansion card 100. The fastener 20 is pushed back, the pins 221 slide back along the through slots 1282. The resilient portion 28 is deformed to allow the latch 282 to engage in the hooking slot 1262. The limitation tabs 125 are blocked by sidewalls bounding front ends of the first through holes 25. Therefore, the fastener 20 is fastened to the first rack 12. At the same time, the supporting portions 24 slide along a bottom surface of the expansion card 100, to support a front end of the expansion card 100. The front end of the expansion card 100 is sandwiched between the supporting portions 24 and the clamp tabs 23. Thereby, the expansion card 100 is firmly fastened to the first rack 12 and the second rack 13.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fastening device for an expansion card, comprising:
a chassis comprising a first rack, and a second rack behind the first rack to fasten a rear end of the expansion card; and
a fastener pivotably and slidably connected to the first rack, the fastener forming a supporting portion;
wherein the fastener is operable to be rotated to a first position where the fastener is in front of the first rack, when the fastener is rotated to a second position where the supporting portion faces the expansion card, the fastener is operable to be slid back to allow the supporting portion to support a front end of the expansion card.

2. The fastening device of claim 1, wherein a clamp tab is formed on the fastener, when the fastener is rotated to the second position, the clamp tab and the supporting portion are located between the first rack and second rack, the clamp tab is above the expansion card, the supporting portion is below the expansion card, when the fastener is slid back, the front end of the expansion card is sandwiched between the clamp tab and the supporting portion.

3. The fastening device of claim 1, wherein the fastener comprises a latch, the first rack defines a hooking slot, when the supporting portion supports the front end of the expansion card, the latch engages in the hooking slot.

4. The fastening device of claim 3, wherein the fastener comprises a base plate, the base plate defines a first through hole, a resilient portion is formed on the base plate and is extended through the first through hole, the latch is formed on the resilient portion.

5. The fastening device of claim 4, wherein a first supporting tab extends forward form the first rack, when the fastener is rotated to the second position, the base plate is supported on the first supporting tab.

6. The fastening device of claim 5, wherein an engaging portion extends down from the first supporting tab, the hooking slot is defined in the engaging portion.

7. The fastening device of claim 5, wherein a top of the first rack defines an opening, the first supporting tab extends from a bottom wall bounding the opening.

8. The fastening device of claim 7, wherein two stop tabs extend forward from opposite sidewalls of the opening, when the fastener is rotated to the second position, opposite ends of the base plate are blocked by the stop tabs.

9. The fastening device of claim 5, wherein a limitation tab extends up from the first supporting tab, the base plate defines a second through hole, when the fastener is rotated to the second position, the limitation tab extends through the second through hole, the fastener is slid back, the limitation tab is blocked by a sidewall bounding a front end of the second through hole.

10. The fastening device of claim 4, wherein two extension portions extend forward from the first rack, the fastener is located between the extension portions, two pivoting plates are formed on opposite ends of the base plate, each pivoting plate is pivotably and slidably connected to the corresponding extension portion.

11. The fastening device of claim 10, wherein each extension portion defines a through slot, a pin is formed on each pivoting plate to pivotably and slidably extend through the corresponding through slot.
